(19) United States
(12) Patent Application Publication
(10) Pub. No.: US 2026/0040866 A1
(43) Pub. Date: Feb. 5, 2026

(54) CHAMBER FOR PROCESSING SUBSTRATES AT HIGH TEMPERATURES

(71) Applicant: Applied Materials, Inc., Santa Clara, CA (US)

(72) Inventors: Christian GRONET, Santa Clara, CA (US); Brian BURROWS, San Jose, CA (US); David Masayuki ISHIKAWA, Mountain View, CA (US); Kelvin CHAN, San Ramon, CA (US)

(21) Appl. No.: 18/792,481

(22) Filed: Aug. 1, 2024

(51) Int. Cl. H01L 21/67; C23C 16/32; C23C 16/44; C23C 16/455; C23C 16/458; C23C 16/46; C30B 25/10; C30B 25/12; C30B 25/14; C30B 25/20; C30B 29/36; H01L 21/04; H01L 21/324

(52) U.S. Cl. CPC H01L 21/67115; C23C 16/325; C23C 16/4408; C23C 16/4411; C23C 16/45519; C23C 16/45565; C23C 16/4584; C23C 16/46; C30B 25/10; C30B 25/12; C30B 25/14; C30B 25/20; C30B 29/36; H01L 21/0445; H01L 21/324; H01L 21/67248

(57) ABSTRACT

Disclosed herein are a processing chamber and a method for processing a SiC substrate. The processing chamber includes a gas showerhead; a susceptor disposed below the gas showerhead, the gas showerhead configured to flow a process gas toward the susceptor; a protective region disposed below the susceptor; and a heating assembly having a front side facing directly a backside of the susceptor. The heat assembly further includes a plurality of lamps. Both the backside of the susceptor and the front side of the heating assembly are exposed to the protective region. The lamps are also exposed to the protective region. The processing chamber includes a chamber body formed by a lid shielded by a lid liner, an upper side section shielded by a side liner, a lower side section, and a bottom section. The lid includes cooling channels. The upper side section also includes cooling channels.

### BACKGROUND

### Field

The present disclosure relates to a processing chamber and method for processing substrates at high temperatures, and, more specifically, relates to a processing chamber and method for processing a SiC substrate.

### Description of the Related Art

Silicon carbide (SiC) devices have been getting more and more attention in the semiconductor industry. Compared to silicon, SiC has a wider band gap, higher electric conductivity, and higher thermal conductivity. Due to the wider band gap, semiconductor devices made of SiC can have a higher breakdown voltage and be operated at a higher frequency than silicon devices. Thus, SiC devices are suitable for high-power and high-voltage applications. SiC also has a higher melting point than silicon, which is desirable by power electronics and high-temperature applications.

Making SiC devices is challenging partially because SiC substrates need to be processed at a much higher temperature than silicon substrates. For example, a temperature range of 1,500° C. to 1,800° C. is used to deposit a SiC film, while a silicon film can be deposited between 500° C. to 1,000° C. Moreover, a SiC substrate is typically thinner and more easily stressed as compared to a silicon substrate, making the SiC substrate more prone to warping when being subject to a rapid thermal treatment. The conventional technologies have not provided a satisfying solution to the warping problem of a SiC substrate.

In addition, conventional processing chambers have several drawbacks in processing SiC substrates. For example, the heating rate of a conventional processing chamber is slow, such as less than 4° C./second, which can undesirably limit the throughput of a high temperature process. Certain components are made of materials that have a low melting temperature, which can suffer damage at high temperatures. For example, any quartz parts, such as lamp housing, can melt at high temperatures.

Thus, a need exists for an improved processing chamber for processing a SiC substrate.

### SUMMARY

Disclosed herein are a processing chamber and a method for processing a substrate at a high temperature range. The substrate may be a SiC substrate. In an example, the processing chamber includes a gas showerhead configured to flow a process gas into the processing chamber; a susceptor disposed below the gas showerhead and configured to support a substrate, the gas showerhead configured to flow a process gas toward the susceptor; a protective region disposed below the susceptor; and a heating assembly having a front side directly facing a backside of the susceptor. The heating assembly has a plurality of lamps configured to emit radiation for heating the susceptor. Both the backside of the susceptor and the front side of the heating assembly are disposed in the same protective region. The plurality of the lamps are also exposed to the protective region.

In an example, the processing chamber includes a chamber body formed by a lid shielded by a lid liner, an upper side section shielded by a side liner, a lower side section, and a bottom section. The lid includes a plurality of first cooling channels disposed along an inside surface of the lid. The upper side section includes a plurality of second cooling channels disposed along an insider surface of the upper side section. The processing chamber further includes an edge ring coupled to the upper side section and configured to support a susceptor, the lid and the upper side section enclosing a first processing volume above the susceptor, the lower side section and the bottom section enclosing a second processing volume below the susceptor. The processing chamber further includes a gas showerhead coupled to a roof of the lid and configured to flow a process gas toward the susceptor; and a heating assembly disposed below the susceptor and including a reflector.

In an example, the method includes rotating a susceptor supporting a substrate at a first rotational speed that is lower than a deposition speed; heating the substrate to a first temperature that is lower than a deposition temperature by a heating assembly; reducing a warpage of the substrate at the first temperature and the first rotational speed; increasing a temperature of the substrate to the deposition temperature and a rotational speed to the deposition speed; flowing a purge gas around a surface of a liner of the processing chamber; and flowing a source gas into the processing chamber in a direction that is parallel with a rotational axis of the susceptor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of a deposition chamber, according to an embodiment of the present disclosure.

FIG. 3 illustrates a perspective cross-sectional view of a heating assembly, according to an embodiment of the present disclosure.

FIG. 4A illustrates a schematic cross-sectional view of a reflector pocket, according to an embodiment of the present disclosure.

FIG. 4B illustrates a schematic top view of a heating assembly, according to an embodiment of the present disclosure.

FIG. 5 illustrates a schematic configuration of a warp sensor, according to an embodiment of the present disclosure.

FIG. 6 illustrates a method for controlling warpage of a substrate, according to an embodiment of the present disclosure.

FIG. 7 illustrates a schematic partial cross-section view of an upper section of a processing chamber, according to an embodiment of the present disclosure.

FIG. 8 illustrates a method 800 for operating a processing chamber at a high temperature, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are a processing chamber and method for processing a substrate at a high temperature range. The processing chamber includes improvements configured to heat and cool a substrate rapidly, reduce the warpage of the substrate, and reduce deposition on undesirable locations/parts of the processing chamber. In an example, the processing chamber has a thin susceptor that is suitable for processing a SiC substrate disposed thereon. The processing chamber is configured to rotate the substrate and the susceptor at a very high rotational speed, such as at least 900 RPM, 1,200 RPM, at least 1,500 RPM, or at least 2,000 RPM. The processing chamber also has a gas showerhead having gas inlets placed above the substrate and configured to flow process gases toward the substrate in a direction that is parallel with the rotational axis of the substrate. A heating assembly having high powered heating elements is disposed under the substrate for heating. The heating assembly may be disposed within the processing chamber, which enhances the substrate heating and cooling rates, thereby contributing to increased substrate throughput.

For heating and cooling a substrate rapidly, the heating assembly is disposed in a close proximity below a susceptor and has high powered heating elements of at least 600 w, at 800 W, at least 1,000 W, or even high power. In one example, heating assembly may be no greater than 10 mm away from the susceptor. The heating assembly is capable of rapidly heating up the substrate at a rate of at least 10° C./second, at least 20° C./second, or at least 30° C./second, or at least 40° C./second or at least 100° C./second. The heating assembly also includes cooling channels surrounding reflectors and capable of maintaining a surface temperature of the reflectors to be no greater than 200° C., no greater than 100° C., or no greater than 50° C., thus allowing greater power density with higher temperatures.

To control the warpage of a SiC substrate which undergoes a rapid thermal processing, the processing chamber includes a warpage control system coupled with the heating assembly. The heating elements of the heating assembly are divided into a plurality of heating zones, and the warpage control system adjusts the power of each heating zone based on a curvature profile of the substrate. The operation to reduce warpage is implemented by the warpage control system before the substrate reaches a deposition temperature.

To reduce the deposition of materials at undesirable locations/parts of the processing chamber, chamber walls and liners surrounding a processing volume defined within the processing chamber include internal cooling channels to keep the temperature of the chamber walls and liners low. A cooled chamber wall and liner can reduce material deposition on their surfaces and prolong the service period before maintenance. A purge gas may also be flowed along the surfaces of the chamber walls and liners to shield the surfaces from other process gases. Components that are placed under the substrate are shielded by a protective region located right under the susceptor. Purge gas is present in the protective region at a pressure slight higher than the pressure within the processing volume that is above the susceptor. The higher pressure of the protective region can prevent any process gas from entering the space that is below the susceptor.

A processing chamber as set forth in the present disclosure can have an increased throughput in processing substrates at high temperatures and improved uniformity in the processing result. The processing chamber can also be operated for a long period of time without needing to swap out the liner or clean the chamber walls for maintenance. The process chamber also reduces the incidences where warped substrates may fly out of a susceptor.

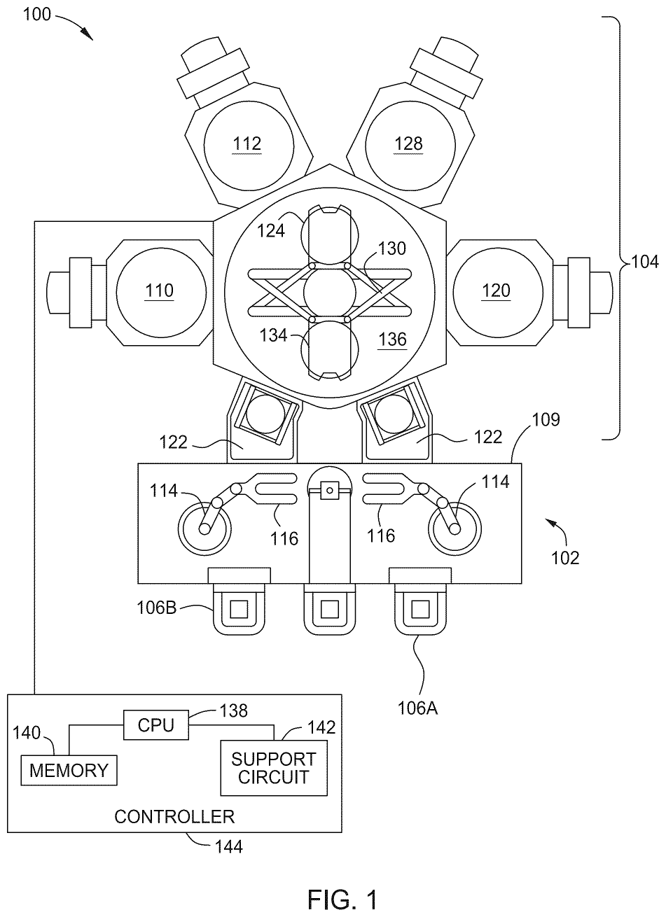

FIG. 1 illustrates a schematic top view of a processing system 100, according to one or more embodiments. According to an embodiment, the processing system 100 includes a processing chamber set forth in various embodiment of the present application. The processing system 100 includes one or more load lock chambers 122 (two are shown in FIG. 1), a processing platform 104, a factory interface 102, and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, and a transfer chamber 136. The plurality of processing chambers 110, 112, 120, 128 may include an atomic layer deposition (ALD) chamber, an epitaxy deposition (EPI) chamber, a physical vapor deposition (PVD) chamber, a chemical vapor deposition (CVD) chamber, a molecular beam epitaxy (MBE) chamber, an etch chamber, a rapid thermal processing (RTP) chamber, or any other substrate processing chamber. In an embodiment, the plurality of processing chamber 110, 112, 120, 128 include an EPI chamber configured to process a silicon carbide (SiC) substrate at a temperature range of at least 1,000° C., at least 1,200° C., at least 1,400° C., or at least 1,800° C. and to deposit an epitaxial SiC film on the SiC substrate.

Each of the processing chambers 110, 112, 120, 128 is coupled to the transfer chamber 136. The transfer chamber 136 can be maintained under vacuum. The factory interface 102 is coupled to the transfer chamber 136 through the load lock chambers 122. Two load lock chambers 122 are shown in FIG. 1. The load lock chambers 122 are used to transfer substrates from an ambient (e.g., atmospheric) pressure environment of the factory interface 102 to the vacuum environment of the transfer chamber 136.

In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 has a blade 116 that is configured to transfer one or more substrates from the FOUPS 106A to the load lock chambers 122.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

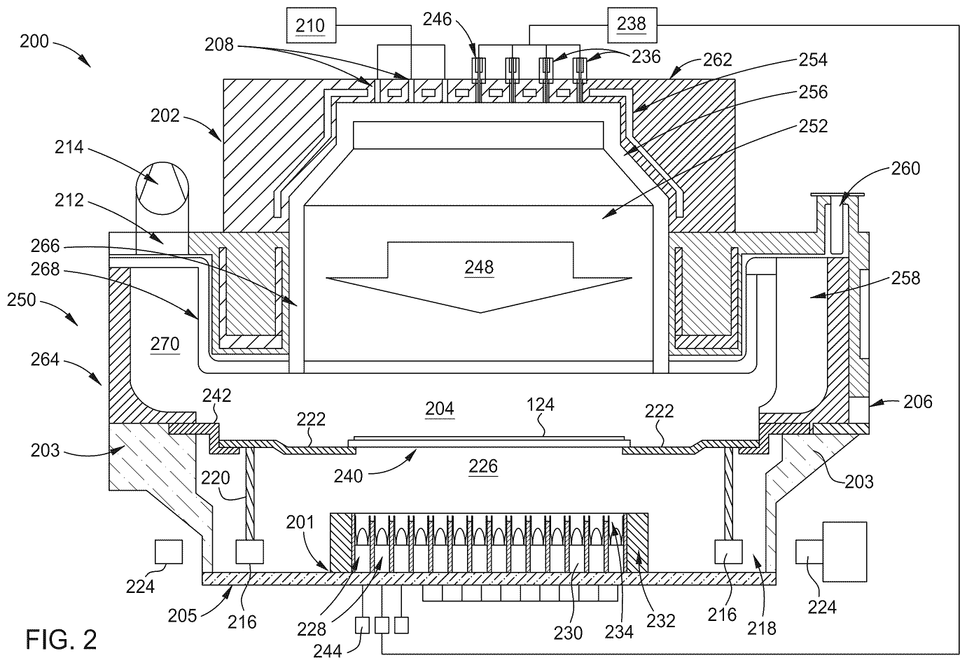

FIG. 2 illustrates a schematic cross-sectional view of a processing chamber 200, according to an embodiment of the present disclosure. The processing chamber 200 can be one or more of the processing chambers 110, 112, 120, and 128 as shown in FIG. 1. In an embodiment, the processing chamber 200 functions as an epitaxy deposition chamber configured to deposit one or more layers of materials on a substrate 124, which may a SiC substrate or any other substrate that is processed at a high temperature. The processing chamber 200 includes a controller 238 coupled with other components of the processing chamber and configured to operate the various components and processing operations of the processing chamber 200.

The processing chamber 200 includes a chamber body 250, which includes a lid 202, an upper side section 264, a lower side section 203, and a bottom section 205. The lid 202 is supported on the upper side section 264 of the body 250. The chamber body 250 encloses an internal volume in which a susceptor 240 is positioned to support a bottom surface of the substrate 124 during processing. A portion of internal volume disposed above the susceptor 240 includes a processing volume 204. The processing chamber 200 also includes a lid liner 252 disposed inside the lid 202 and conforms to the shape of the interior walls of the lid 202. The lid liner 252 shields the lid 202 from process gases 248 contained in the lid 202, thus protecting the lid 202 from receiving any deposited materials. The lid liner 252 may have material deposition and may be replaced with a new liner after a period of usage. The processing chamber 200 also includes a side liner 266 and an exhaust liner 268. The side liner 266 conforms to the shape of the interior walls of the upper side section 264 and protecting the upper side section 264 from receiving any deposited materials. The exhaust liner 268 is disposed along the exhaust channels 270 to protect the exhaust channels 270 from receiving any deposited materials. Like the lid liner 252, the side liner 266 and the exhaust liner 268 may be replaced after a period of usage.

To control the temperatures of the processing chamber 200, the lid 202 includes a plurality of cooling channels 254. The lid liners 252 also includes a plurality of cooling channels 256. The cooling channels 254 may be coupled with the cooling channels 256 so that a same coolant is circuited through both the cooling channels 254 and the cooling channels 256. The cooling channels 254 and 256 are divided into a plurality of cooling zones, each of which can be independently controlled to cool a section of the lid 202 and the lid liner 252. The lid 202 and the lid liner 252 can be made of stainless steel, nickel containing super alloy, such as Inconel, or any other suitable material. In an embodiment, both the lid 202 and the lid liner 252 are made of Inconel manufactured by an additive manufacturing process, such as a 3D-Printing process. Configurations of the lid 202 and the lid liner 252 will be provided later in detail with reference to other drawings. Similar with the lid 202 and the lid liner 252, the upper side section 264 and the side liner 266 may also include cooling channels for controlling their temperatures.

A slit 206 may be formed on between the upper side section 264 and the lower side section 203 for providing a passage for the substrate 124 to be transferred in and out of the processing chamber 200. A movable side section 258 is positioned in front of the slit 206 to open or close the slit 206. A motor 260 is coupled with the movable section 258 to lift it up or lower it down.

A gas showerhead 208 is disposed on the roof 262 of the lid 202 and is coupled to one or more gas sources 210 via one or more gas conduits to provide process gases, such as a source gas, a carrier gas, a purge gas, and a cleaning gas, to the processing volume 204. In an embodiment, the substrate 124 includes a SiC substrate, and the process gases include a silicon (Si) source gas, a carbon source gas, an additive gas, a carrier gas, or any other suitable gas, or a combination of such gases. The gases may originate from separate gas sources 210. The gases may be mixed together in a mixing manifold and provided to the showerhead 208 via one or more gas conduits. Alternatively, the gases may be kept separate and provided via separate gas conduits to the showerhead 208, and then mixed together in the processing volume 204. The gases can react to deposit a SiC epitaxial film on the substrate 124. The Si source gas may include monosilane, dichlorosilane, trichlorosilane, silicone tetrachloride, or any other suitable Si source gas. The carbon source gas may include propane, acetylene, ethylene, or any other suitable carbon source gas. The additive gas may include a hydrogen chloride gas or a dopant gas. The carrier gas may include a hydrogen (H2) gas or an inert gas, such as helium, argon, or other inert gas. A vacuum pump 214 may be fluidly connected to the processing volume 204 through an outlet 212 for pumping out effluent gases. In an embodiment, the gas source 210 may include a silicon gas source, a carbon gas source, a carrier gas source, or an additive gas source. SiC is one example of a compound semiconductor, and in other embodiments the chamber can be used with other process gases to deposit other compound semiconductor films such as Gallium nitride (GaN), Gallium arsenide (GaAs), or Indium phosphide (InP).

As discussed above, the substrate 124 is supported within the interior volume of the processing chamber 200 by the susceptor 240. The susceptor 240 may have a disc shape and be made of any suitable material, such as SiC, graphite coated with SiC, or other material. The susceptor 240 may also be very thin, such as no greater than 2 mm, or no greater than 1.5 mm, or no greater than 1.0 mm, for fast thermal transmission. The susceptor 240 is supported by an edge ring 222 disposed on a tubular member 220. An outer ring 242 covers a gap between the side section 203 and the edge ring 222. The tubular member 220 rests on or otherwise coupled to a rotational mechanism, such as a magnetic rotor 216. The magnetic rotor 216 is disposed in the circular channel 218. A magnetic stator 224 is located externally of the magnetic rotor 216 and is magnetically coupled through the side section 203 to induce rotation of the magnetic rotor 216 and hence of the edge ring 222 and the substrate 124 supported thereon. The magnetic stator 224 may be also configured to adjust the elevations of the magnetic rotor 216, thus lifting up or lowering down the substrate 124. The magnetic rotor 216 is capable of rotating the edge ring 222 and the susceptor 240 at a rotational speed of at least 900 RPM, at least 1,200 RPM, at least 1,500 RPM, or at least 2,000 RPM.

A heating assembly 201 is disposed below and in close proximity to the susceptor 240 for heating the substrate 124 efficiently. To heat the substrate 124 disposed on the susceptor 240 efficiently, the heating assembly 201 may be no greater than 10 mm, or no greater than 5 mm away from the susceptor 240. Alternatively, the heating assembly 201 may be spaced from the susceptor 240 a distance greater than 10 mm. The heating assembly 201 includes a plurality of heating elements 228 configured to emit radiation for heating the susceptor 240. The heating elements 228 may be UV lamps, halogen lamps, laser diodes, resistive heaters, microwave powered heaters, light emitting diodes (LEDs), or any other suitable heating elements both singly or in combination. In an embodiment, the heating elements 228 include UV lamps and are disposed in reflector pockets 230 formed in a reflector assembly 232 of the heating assembly 201.

Cooling channels 234 are formed in the reflector assembly 232. The circulation of a heat transferring fluid in the cooling channels is capable of keeping a surface temperature of the reflectors 232 within a desired operational range, which, in some examples, is be no greater than 100° C., no greater than 50° C. In an embodiment, the substrate 124 is heated to a temperature of at least 1,500° C., and a temperature of a top surface of the heating assembly 201 is no higher than 50° C. The heating assembly 201 may be referred to as a lamphead.

In one embodiment, the heating elements 228 may be divided into a plurality of heating zones to heat the substrate 124. Each heating zone may be controlled independently by the controller 238 to supply heat to the susceptor 240 and the substrate 124. A heat transferring fluid, such as water, may be circulated inside the cooling channels 234. Configurations of the heating assembly 201 will be provided in detail later with reference to other drawings.

A protective region 226 is defined in the internal volume of the processing chamber 200 between the heating assembly 201 and the susceptor 240. The protective region 226 is configured to protect components disposed between the susceptor 240 and the bottom section 205, such as the backside of the susceptor 240 and the heating assembly 201. In an embodiment, the protective region 226 is a volume which is substantially filled with a purge gas, such as helium, nitrogen or other inert or otherwise suitable gas, to prevent process gases in the processing volume 204 from reaching the backside of the susceptor 240 and the heating assembly 201, thereby preventing deposition on such components. The purge gas may be flowed into the protective region 226 via at least one gas port disposed in the heating assembly 201. In an embodiment, each reflector pocket 230 includes at least one gas port for flowing the purge gas. The processing volume 204 and the protective region 226 may have different environments, such as different gases, different gas pressures, and different temperatures. In an embodiment, the pressure of the protective region 226 is higher than the processing volume 204. The protective region 226 is separated from the processing volume 204 by the susceptor 240, edge ring 222 and outer ring 242.

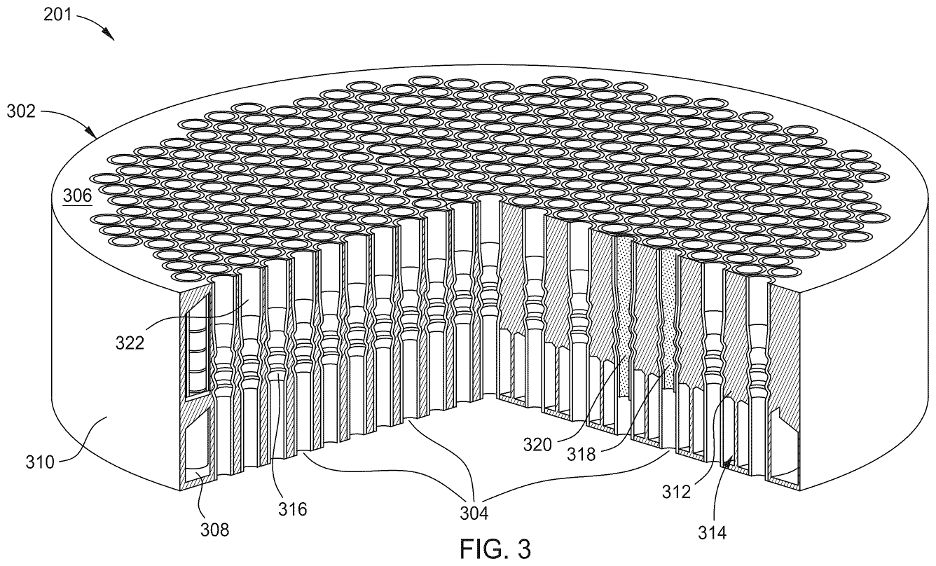

In an embodiment, the protective region 226 is configured to reduce any unnecessary loss of radiation emitted by the heating assembly 201. For example, the protective region 226 is very thin, such as no thicker than 10 mm, or no thicker than 5 mm, or even thinner. In another example, only gases are disposed in the protective region 226. No other intervening parts or components are disposed in the protective region 226 that could interfere with the radiation emitted by the heating assembly 201. A traditional processing chamber may include a transparent window disposed between the susceptor 240 and the heating elements 228 (e.g. lamps) of the heating assembly 201 for protection. The processing chamber 200 of the present disclosure includes no such transparent or protective window in the protective region 226, according to an embodiment. Instead, a purge gas is used for protecting the heating elements 228 (e.g. lamps) of the heating assembly 201. The heating elements 228, front side (shown as 306 in FIG. 3) of the heating assembly 201, and the back side of the susceptor 240 are disposed in and exposed to the same protective region 226 (and exposed to the same purge gas within the protective region 226) and arranged to face each other directly. The radiation emitted by the heating elements 228 and heating assembly 201 can reach the susceptor 240 directly, only subject to any interference with the purge gas that may fill the protective region 226.

In an embodiment, a plurality of backside thermal sensors 244 may be disposed below the substrate 124 and the susceptor 240. The backside thermal sensors 244 are configured to measure temperatures at a backside of the susceptor 240 by measuring a blackbody emission of the susceptor at a first wavelength. The backside of the susceptor 240 may include surface treatments to increase the emissivity of the back of the susceptor. The surface treatments include laser patterning or an oxidation layer. A plurality of topside thermal sensors 236 may be disposed in the roof 262 of the lid 202. The topside thermal sensors 236 measure temperatures at a topside of the substrate 124. The topside thermal sensors 236 are configured to measure temperatures by measuring a blackbody emission of the substrate 124 at a second wavelength. In an embodiment, the first wave length is longer than the second wavelength. In an example, the first wavelength is at least 3 um, such as about 5.2 um. The second wavelength is between about 500 nm and about 3 um. The topside thermal sensors 236 and the backside thermal sensors 244 are capable of measuring temperatures at a high frequency, such as at least 30 Hz, or at least 60 Hz, or at an even higher frequency.

The processing chamber 200 may also include a plurality of warp sensors 246 disposed in the roof 262 of the lid 202. The warp sensors 246 are pointed to different locations of the substrate 124 and configured to measure a warpage profile of the substrate 124. In an embodiment, the warp sensors 246 may be part of the topside thermal sensor 236. The warp sensor 246 is configured to measure the warpage profile by emitting a light at a third wavelength. The third wavelength may be between 500 nm and about 3 um.

The controller 238 is coupled with the thermal sensors 236, 244 and the warp sensors 246. In an embodiment, the controller 238 controls powers of the heating assembly 201 according to signals provided by the thermal sensors 236, 244, and the warp sensors 246. The controller 238 also controls a rotational speed of the susceptor 240 and the substrate 124. The controller 238 may also control other components of the processing chamber 200, such as the pump 214, the gas source 210, and other components.

FIG. 3 illustrates a schematic perspective and cross-sectional view of the heating assembly 201, according to an embodiment of the present disclosure. The heating assembly 201 includes a base 302 and a plurality of reflector pockets 304 formed in the base 302. In an embodiment, the base 302 has a cylindrical shape formed by a radiation side 306, a socket side 308, and a side wall 310. The radiation side 306 may also be understood as the front side as the radiation side 306 faces the susceptor and allows radiation to pass through. The radiation side 306 and the socket side 308 form two opposite sides of the base 302. The radiation side 306 faces a susceptor and allows radiation emitted by heating lamps to pass through. The socket side 308 includes a plurality of sockets configured to couple with the heating lamps. The socket side 308 faces away from the susceptor and is disposed at a side opposite to the radiation side 306. When the heating assembly is positioned below the susceptor 240 (shown in FIG. 2), the radiation side 306 defines a top surface of the base 302, and the socket side 308 defines a bottom surface of the base 302. The side wall 310 extends between the radiation side 306 and the socket side 308.

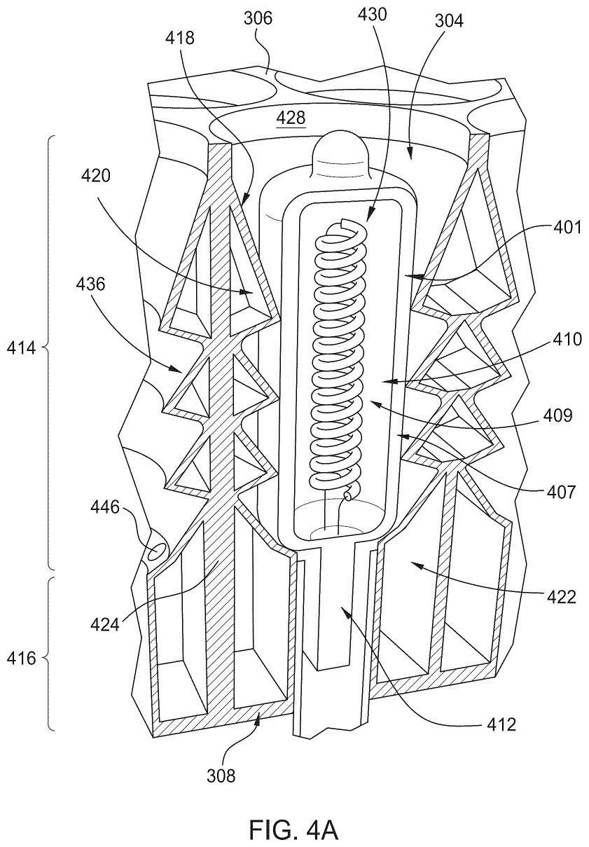

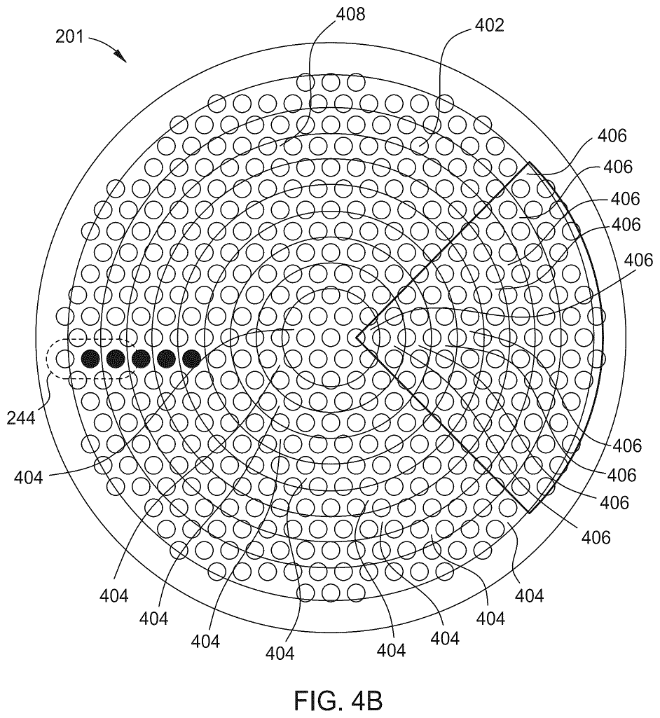

The plurality of reflector pockets 304 are configured to receive a heat element 228 (shown in FIG. 2), such as a radiation lamp (later shown in FIG. 4). Each reflector pocket 304 includes a reflector 322 configured to reflect radiation emitted by the heating element 228 toward the radiation side 306 and/or the susceptor 240 disposed above the radiation side 306. Each reflector pocket 304 is cooled by a heat transferring fluid, such as water. In an embodiment, a purge gas, such as helium, nitrogen or other inert gas, may also be flowed through the reflector pocket for cooling.

The base 302 includes a reflector cooling chamber 312 and a base cooling chamber 314. The reflector cooling chamber 312 is disposed around the reflector 322 and is configured to cool the reflector. The base cooling chamber 314 is disposed under the reflector cooling chamber 312 and is configured to cool a coupling portion between the reflector pocket and a heating element. Details of the cooling chambers 312, 314 will be later described with reference to FIG. 4A.

The heating assembly 201 may include a structure made by an additive manufacturing process, such as a 3D printing process. With an additive manufacturing process, the heating assembly 201 can have complex shapes, such as a Fresnel shape 316 for the reflector 322. The structures of the shapes can also be very thin, such as no greater than 1 mm thick. For example, walls made from nickel-based supper alloy may be no greater than 1 mm thick and form the reflector 322. The structure made by the additive manufacturing process can be subsequently polished and coated by layers of protective materials and/or layers of reflective materials, such as gold. The structure made by the additive manufacturing process may be made of nickel, a nickel-based super alloy (such as INCONEL®), stainless steel, copper, and any other suitable material.

In an embodiment, at least one reflector pocket 304 is not occupied by a heating element. A light pipe 320 of a pyrometer can use the unoccupied reflector pocket 304 as a passage to measure the temperature of a substrate. A sleeve 318, such as a sapphire sleeve, may be additionally disposed within the unoccupied reflector pocket 304 to protect the light pipe of the pyrometer.

FIG. 4A illustrates a schematic cross-sectional view of a reflector pocket 304 of the heating assembly 300, according to an embodiment of the present disclosure. The cross-sectional view shows that a heating element 401, such as a radiation lamp, is disposed in the reflector pocket 304. The heating element 401 and the reflector pocket 304 are included in the heating assembly 300 as shown in FIG. 3. In an embodiment, the heating element 401 has a heating power of at least 600 W, at least 800 W, at least 1,000 W, or even higher. The reflector pocket 304 is configured to direct a large portion of the radiation emitted by the heating element out of the reflector pocket 304. The reflector pocket 304 is also configured to have sufficient cooling capacities such that the heating element 401 can be operated for extended periods without suffering heat related damage. In an example, the configuration of the cooling chambers, the thin structure of the reflector, and the purge gas passing through the reflector pockets are configured to quickly and efficiently remove a large amount of heat from the reflector, thus keeping the temperature of a reflector wall 418 below 100° C., or below 50° C. A heating element 401 disposed in the reflector pocket 304 can be operated at least at 800 W for longer than 10 minutes without showing any damage, such as deformation or meltdown of an external housing.

As shown in FIG. 4A, the heating element 401 includes a radiation portion 410 and a coupling portion 412. The radiation portion 410 includes a filament 409 enclosed by a housing 407. During operation, the filament 409 generates radiation which can be absorbed by a susceptor to generate heat. The radiation can also be absorbed by and heat other components of the heating assembly 300, which may not desired. The housing 407 protects the filament and may be made of a transparent material, such as quartz. The coupling portion 412 is configured to secure the heating element 401 in the reflector pocket 304. The coupling portion 412 includes electrical connections that supply electricity to the filament 409. Adjacent to the coupling portion 412 is a base cooling chamber 422 which cools the coupling portion 412.

In an embodiment, the reflector pocket 304 is divided into a reflector portion 414 and a base portion 416. The reflector portion 414 is disposed at locations that surround the radiation portion 410 of the heating lamp 401 and includes reflective surfaces configured to direct radiation of the heating element 401 toward predetermined directions. The base portion 416 is disposed below the reflector portion 414 and adjacent to the bottom wall 308 of the heating assembly 300. The base portion 416 is configured to engage with and secure the coupling portion 412 of the heating lamp 401. In an embodiment, both the reflector portion 414 and the base portion 416 include 3D printed materials, which may include nickel, nickel-containing supper alloy (Inconel), stainless steel, copper, or any other suitable material. The 3D printed materials are thin and allow the coolant to be immediately adjacent to the heating lamp, which cool the lamp more efficiently than other materials. As a result, the heating lamp can have a very high power, such as at least 600 W, at least 800 W, at least 1,000 W, or even higher power.

In an embodiment, a purge gas outlet 446 is disposed inside the reflector pocket 304. The purge gas outlet 446 allows a purge gas, such as helium, to flow into each reflector pocket. The flow of the purge gas can cool the heating element 401 and fill the protective region 226. The purge gas outlet 446 may be disposed at any location that is above the coupling portion 416 and below the heating filament 406.

In an embodiment, the reflector portion 414 may include several sections configured to direct radiation toward predetermined directions. The reflector portion 414 may include a cylindrical section 428 and a Fresnel section 436. The cylindrical section 428 is disposed adjacent to the radiation side 306 and above a top end 430 of the filament 409. The Fresnel section 436 substantially surrounds the filament 409. In an embodiment, the Fresnel section 436 has a plurality of upward facing surfaces facing toward the radiation side 306 and a plurality of downward facing surface facing toward the bottom wall 308. The upward facing surfaces and the downward facing surfaces form a Fresnel shape.

A reflector cooling chamber 420 is formed behind the reflector wall 418. The reflector cooling chamber 420 allow a heat transferring fluid, such as water, to be circulated to remove heat from the reflector wall 418, which, in turn, lowers the temperature of the housing 407. The reflector cooling chamber 420 may form a cooling jacket encasing the heating element 401.

The base portion 416 of the reflector pocket 304 includes a base cooling chamber 422 configured to circulate the heat transferring fluid (not shown), such as water. The base cooling chamber 422 surrounds and cools the coupling portion 412 of the heating element 401. In an embodiment, the base cooling chamber 422 functions as a return plenum and fluidly connected with the reflector cooling chamber 420. The base cooling chamber 422 receives the heat transferring fluid from the reflector cooling chamber 420 and directs the heat transferring fluid to an outlet (not shown). A supply plenum (not shown) is used to supply the heat transferring fluid to the cooling chamber 520.

In an embodiment, the reflector pocket 304 also includes a vertical wall 424 extending between the radiation side 306 and the bottom wall 308. The reflector portion 414 is attached to the vertical wall 424. In one or more embodiments, the reflector cooling chamber 520 extends to a location higher than the top end 430 of the filament 409.

FIG. 4B illustrates a schematic top view of a heating assembly 201, according to an embodiment of the present disclosure. The heating elements 402 of the heating assembly 201 may be divided into a plurality of heating zones 408. The heating zones 408 may be arranged in a honeycomb, grid, or other arrangement. In an embodiment, the heating zones include annular bands, which are concentric to one another. Each annular band may be divided into two heating zones 404 and 406, which are complementary circular sectors. The heating zone 404 include a plurality of heating elements 402 and may have a circular angle greater 180 degrees. The heating zone 404 are configured to constantly supply energy to the processing chamber. Each heating zone 404 may include one or more cooling chambers. The heating zone 406 also include a plurality of heating elements 402 and may have a circular angle less than 180 degrees (i.e., the heating zones 408 may be configured as an arc segment). The zone groups 406 are configured to intermittently supply energy to the processing chamber. Power of each of the heating zones 404, 406 can be independently adjusted. As a result, the uniformity of temperature on a substrate can be better controlled. As shown in FIG. 4, light pipes of a plurality (5 are shown) of backside thermal sensors 244 are also disposed within the heating assembly 201.

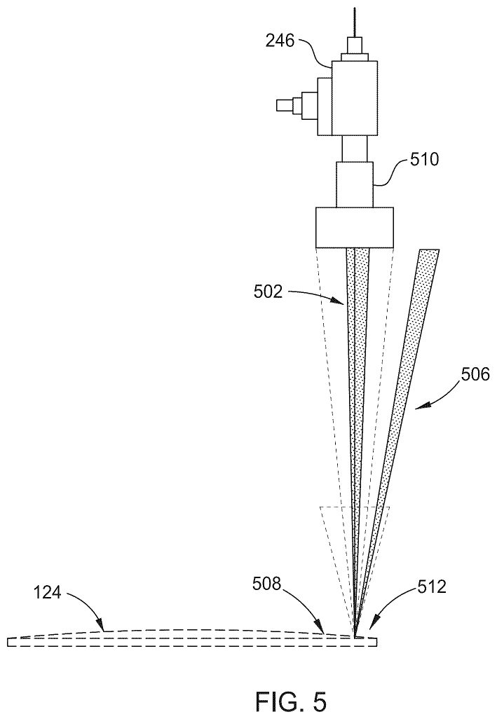

FIG. 5 illustrates a schematic configuration of a warp sensor 246, according to an embodiment of the present disclosure. The warp sensor 246 is capable of measuring a curvature ranging from −10,000 km⁻¹ (convex) to +1,000 km⁻¹ (concave). The warp sensor 246 includes a transceiver head 510 which has a laser emitters and a photodetector. In an embodiment, a laser emitter of the transceiver head 510 emits a laser beam 502 toward a front surface 508 of the substrate 124. The emitted laser beam 502 may has a wavelength ranging from about 400 nm to about 1,000 nm. The emitted laser beam 502 impinges on a location 512 of the surface 508. Depending on the curvature of the substrate 124 at the location 512, the emitted laser beam 502 may be reflected into different directions. When the substrate 124 has very little warpage at the location 512, a large portion of a reflected laser beam 506 can travel back to the transceiver head 510. The photodetector of the transceiver head 510 can detect an intensity of the received laser beam 506. As the warpage of the substrate 124 directly affects the amount of the reflected beam 506 that can reach the transceiver head 510, the controller 238 (shown in FIG. 2) can determine a curvature of the surface 508 based on the intensity of signals corresponding to the received reflected laser beam 506. When a plurality of the warp sensors 246 are installed, a warpage profile showing curvature across the front surface 508 can be obtained.

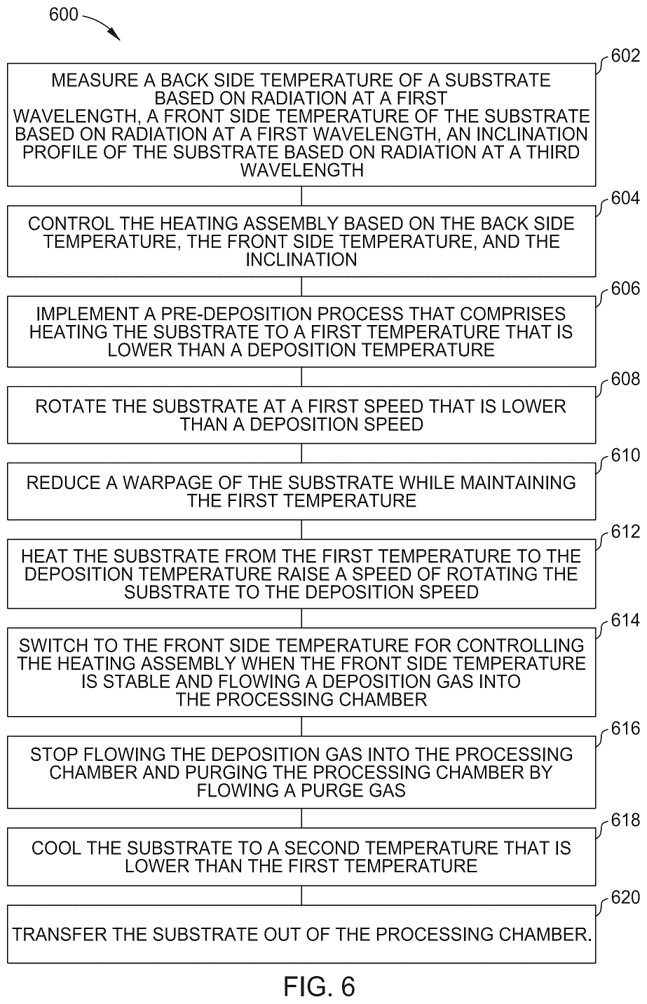

FIG. 6 illustrates a warpage control method 600 of a substrate processing chamber, according to an embodiment of the present disclosure. The processing chamber is capable of processing a SiC substrate at a high temperature ramping-up rate (such as between about 10° C./second and 100° C./second) without causing unacceptable large warpage of the SiC substrate. The warpage control method 600 starts with transferring a substrate from a transfer chamber to a substrate processing chamber. During the period when the substrate is being transferred, a purge gas, such as an inert gas, may be flown into the processing chamber for protecting the substrate. Then, a heating assembly starts heating the substrate. The heating assembly includes a plurality of independently controllable heating zones.

At operation 602, both the backside temperature of the susceptor and the topside temperature of the substrate are measured. The backside temperature is measured based on radiation at a first wavelength, while the topside temperature of the substrate is measured based on radiation at a second wavelength. In addition, a curvature profile of the substrate is measured by the warp sensor based on radiation at a third wavelength. In an embodiment, the first wavelength, the second wavelength, and the third wavelength do not overlap with each other. In an example, the first wavelength is at least about 3 um, such as about 5.2 um. The second wavelength and the third wavelength are between about 500 nm and about 3 um.

At operation 604, the controller controls the heating assembly based on the backside temperature of the susceptor, the topside temperature, and the curvature. The heating assembly is configured to evenly and rapidly heat up the substrate. The controller may adjust the power supplied to the heating assembly to control a temperature ramping up rate. The controller may adjust the power to a subset of heat lamps of the heating assembly to control the temperature of a local zone of the substrate or the susceptor. The controller may also adjust forms of a power signal to the heating assembly, such as frequency, intensity, pulsing rate, pulsing period, and other parameters. In an example, the heating assembly heats the substrate at a rate of 40° C./second. The temperature difference across the surface of the substrate is controlled to be no greater than 10° C., 5° C., or 1° C.

At operation 606, a pre-deposition process is implemented that heats the substrate to a first temperature that is lower than a deposition temperature. For example, the first temperature may be between about 1,200° C. and about 1,600° C., while the deposition temperature may be at least 1,500° C. or at least 1,800° C. A cleaning gas and a carrier gas may be supplied in the pre-deposition process to remove any contamination on the surface of the substrate. A source gas for deposition may not be flowed into the processing chamber during the pre-cleaning process.

At operation 608, the substrate is rotated by the susceptor at a first speed that is lower than a deposition speed. In an embodiment, the deposition speed may be as high as 2,000 rpm. The first speed may be between 200 rpm and 500 rpm.

At operation 610, the controller controls the heating assembly to reduce a warpage of the substrate while the first temperature is maintained. The heating assembly is controlled according to the temperature profile measured by the thermal sensors and the warpage profile measured by the warp sensors. As the heating assembly has a plurality of independently controllable heating zones, the controller can adjust the power of each heating zone to control the temperature of a local area, thus generating a uniform temperature profile and reducing the warpage. For example, when a location shows a lower temperature, the power of the heating zone underneath that location may be increased to raise the temperature.

In an embodiment, the controller determines whether the warpage profile is acceptable based on the readings of the warp sensors. In an example, when one or more warp sensors measured a predetermined amount of the reflected laser beam, the controller determines that the warpage file is acceptable.

At operation 612, when the temperature profile or warpage profile meets predetermined criteria, the substrate's temperature is raised from the first temperature to the deposition temperature. The rotational speed of the susceptor is also raised to the deposition speed.

At operation 614, the measurement of the topside temperatures is monitored. Once the measurement of the topside temperatures is stable and uniform, the controller switches to the topside temperature for controlling the heating assembly. As the topside thermal sensors have an emissivity correction system to account of deposited materials, the topside thermal sensors can more accurately measure the temperature than the back side thermal sensors. After the switching to the topside temperature is completed, a deposition gas is provided into the processing chamber for deposition. In an embodiment, the substrate 124 includes a SiC substrate, and the deposition gases include a silicon (Si) source gas, a carbon source gas, an additive gas, a carrier gas, or any other suitable gas. The Si source gas may include monosilane, dichlorosilane, trichlorosilane, silicone tetrachloride, or any other suitable Si source gas. The carbon source gas may include propane, acetylene, ethylene, or any other suitable carbon source gas. The additive gas may include a hydrogen chloride gas or a dopant gas. The carrier gas may include a hydrogen (H2) gas or an inert gas, such as helium, argon, or other inert gas.

At the end of the deposition process, the flowing of the deposition gas into the processing chamber is stopped at operation 616. A purge gas, such as hydrogen or an inert gas, is flowed into the processing chamber to purge the deposition gas and prepare the processing chamber for a removal of the substrate.

At operation 618, the substrate is cooled to a second temperature that is lower than the first temperature. In an embodiment, the substrate can be cooled by flowing a purge gas along the backside of the substrate. The heating assembly is also configured to lower its temperature to assist the cooling of the substrate. The heating assembly not only has the output power reduced, but also circulates a heat transferring fluid, such as water, within a cooling channel inside the heating assembly for cooling. The heating assembly keeps flowing the purge gas through the gas ports in the reflector pockets for cooling. The coolant and the purge gas cool the heating assembly, which, in turn, cools the susceptor. The second temperature may be between 800° C. to 1,200° C. Either the topside temperature or the backside temperature or both may be used to control the heating assembly.

At operation 620, the substrate is transferred out of the processing chamber once the second temperature is reached. A hydrogen gas or a purge gas may be flowing as a protective gas when the substrate is transferred out of the processing chamber. In an embodiment, the susceptor supporting a SiC substrate is transferred out of the processing chamber together with the SiC substrate.

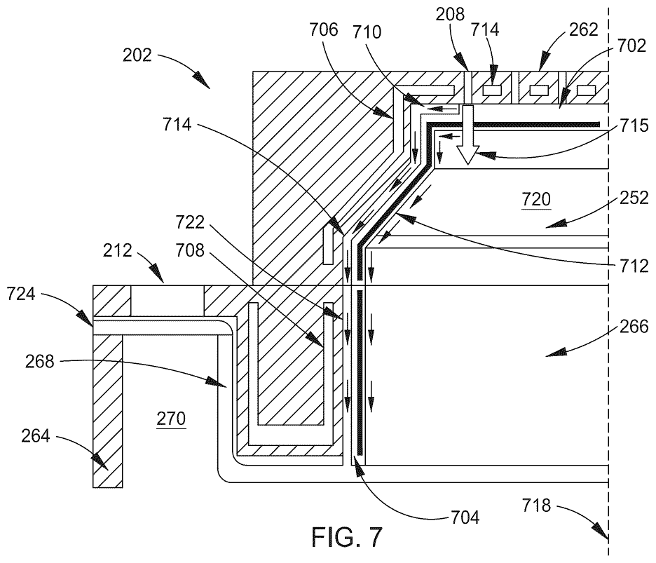

FIG. 7 illustrates a schematic partial cross-sectional view of a lid 202 and an upper side section 264 of the processing chamber 200, according to an embodiment of the present disclosure. The lid 202 is supported by the upper side section 264. The lid 202 includes cooling channels 706 that are disposed along an inside surface 714 of the lid 202 to efficiently remove heat from an internal volume 720. The cooling channels 706 may also extend into the roof 262 of the lid 202.

The upper side section 264 also includes cooling channels 708 disposed along an inside surface 722 of the upper side section 264. The cooling channels 708 may also extend to the exhaust channel 270 of the upper side section 264. The cooling channels 706 may be coupled with cooling channels 708.

Alternatively, the cooling channels 706 and 708 may be independently operated. To have a complex layout pattern of the cooling channels, the lid 202 and the upper side section 264 are made by an additive manufacturing process, such as a 3D-printing process.

The lid 202 and the upper side section 164 include a plurality of liners, such as a lid liner 252, a side liner 266, an exhaust channel liner 268, and an exhaust outlet liner 724. The lid liner 252 is enclosed by the lid 202 and has a shape conforming to the inside surface 714 of the lid 202. The lid liner 252 also includes internal cooling channels 702 as shown in FIG. 7. The cooling channels 706 of the lid 202 and the cooling channels 702 of the lid liner 252 may be fluidly coupled with each other. The side liner 266 is disposed inside the upper side section 264 and couples with the lid liner 252. The side liner 266 includes a plurality of cooling channels 704, which couple with the cooling channels 702 of the lid 202. The exhaust channel liner 268 is disposed along the exhaust channel 270 and is generally L-shaped. The exhaust channel liner 268 extends to the exhaust outlet 212 and couples with an exhaust outlet liner 724. The exhaust outlet liner 724 is disposed along a bottom surface of the exhaust outlet 212.

Similar with the lid 202 and the upper side section 264, the liners 252, 266, 268, and 724 may be made by an additive manufacturing process, such as a 3D-printing process. A material, such as stainless steel, nickel containing supper alloy, or other suitable material, may be used for making the liners.

The gas showerhead 208 is disposed on the roof are configured to provide a plurality of process gases into the processing chamber 200. For example, the gas showerhead 208 provides a flow 716 of a source gas in a direction that is parallel with a central axis 718 of the lid 202. The central axis 718 also functions as the rotational axis of the susceptor 240 or the substrate 124. To reduce deposition of materials at undesirable surfaces, the gas showerhead 208 also provides a first flow 710 of a purge gas to gaps formed between the lid 202 and the liner 252. The gas showerhead 208 also provides a second flow 712 of the purge gas along the surface of the liner 252. The second flow 712 of the purge gas functions as a curtain to protect the liner 252.

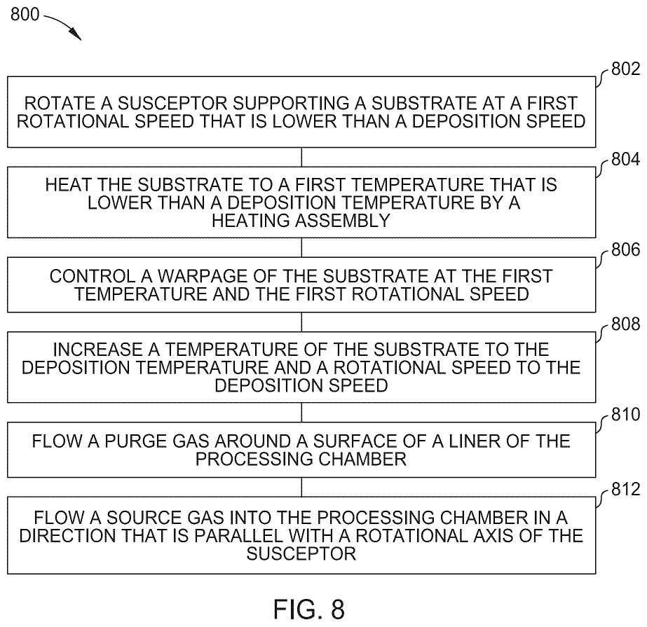

FIG. 8 illustrates a method 800 for operating a processing chamber at a high temperature, according to an embodiment of the present disclosure. The method 800 is configured to rapidly process a SiC substrate at a high temperature. A thin susceptor is utilized to support a SiC substrate in a processing chamber. At operation 802, a magnetic rotation device rotates the susceptor supporting the substrate at a first rotational speed, such as between 200 RPM and 500 RPM. The first rotational speed is lower than a deposition speed, which may be between 1,500 RPM to 2,000 RPM. At operation 804, a heating assembly heats the substrate to a first temperature, which is about 900° C. to 1,200° C. The first temperature is lower than a deposition temperature, which may be between 1,500° C. and 1,800° C. The temperature ramping up rate may be no slower than 10° C./second. At operation 806, the controller implemented a warpage control method for controlling a warpage of the substrate at the first temperature and the first rotational speed. At operation 808, once the implementation of the warpage control method is completed, the heating assembly increases a temperature of the substrate to the deposition temperature, and the magnetic rotation device increases a rotational speed of the susceptor to the deposition speed. At operation 810, the gas showerhead flows a purge gas around a surface of a liner of the processing chamber; and flows a source gas into the processing chamber in a direction that is parallel with a rotational axis of the susceptor. Once the layer of SiC is deposited on the substrate, the temperature is lowered, and the substrate and the susceptor are transferred out of the processing chamber altogether. The method 800 may also include flowing a heat transferring fluid in the heating assembly; and keeping a temperature of a top surface of the heating assembly to be no greater than 50° C.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A processing chamber for processing a substrate, comprising:
a gas showerhead configured to flow a process gas into the processing chamber;
a susceptor disposed below the gas showerhead and configured to support a substrate;
a protective region disposed below the susceptor; and
a heating assembly comprising a front side that directly faces a backside of the susceptor and comprising a plurality of lamps configured to emit radiation for heating the susceptor, wherein both the backside of the susceptor and the plurality of the lamps are exposed to the protective region.

2. The processing chamber of claim 1, wherein the susceptor has a disc shape and couples with an edge ring, the susceptor configured to support the substrate.

3. The processing chamber of claim 2, further comprising:
a rotation mechanism coupled with the edge ring and configured to rotate the edge ring and the susceptor.

4. The processing chamber of claim 1 further comprising:
at least one gas conduit configured to provide the process gas to the gas showerhead, wherein the process gas comprises a silicon containing gas and a carbon containing gas.

5. The processing chamber of claim 1, further comprising one or more gas ports configured to flow a purge gas into the protective region, wherein both the backside of the susceptor and the plurality of the lamps are positioned to be exposed to the purge gas.

6. The processing chamber of claim 5, wherein the heating assembly includes the one or more gas ports, and the purge gas cools both the heating assembly and the susceptor.

7. The processing chamber of claim 1, further comprising:
a chamber body comprising a lid, a lid liner shielding the lid, an upper side section shielded by a side liner, a lower side section, and a bottom section, the lid comprising a plurality of first cooling channels disposed along an inside surface of the lid, the upper side section comprising a plurality of second cooling channels disposed along an inside surface of the upper side section.

8. The processing chamber of claim 7, wherein the gas showerhead is configured to generate a curtain of a purge gas along an inside surface of the lid liner and along a gap between the lid and the lid liner.

9. A processing chamber for processing a substrate comprising:
a chamber body comprising a lid shielded by a lid liner, an upper side section shielded by a side liner, a lower side section, and a bottom section, the lid comprising a plurality of first cooling channels disposed along an inside surface of the lid, the upper side section comprising a plurality of second cooling channels disposed along an inside surface of the upper side section;
an edge ring coupled to the upper side section and configured to support a susceptor, the lid and the upper side section enclosing a first processing volume above the susceptor, the lower side section and the bottom section enclosing a second processing volume below the susceptor;
a gas showerhead configured to flow a process gas toward the susceptor; and
a heating assembly disposed below the susceptor and comprising a reflector.

10. The processing chamber of claim 9, wherein the gas showerhead is configured to generate a curtain of a purge gas along an inside surface of the lid liner.

11. The processing chamber of claim 10, wherein the gas showerhead is configured to flow the purge gas to a gap between the lid and the lid liner.

12. The processing chamber of claim 9, wherein the lid liner comprises a plurality of third cooling channels, and the side liner includes a plurality of fourth cooling channels.

13. The processing chamber of claim 9, wherein the heating assembly includes a reflector pocket, the reflector pocket including a reflector cooling chamber encasing the reflector and a Fresnel shape.

14. The processing chamber of claim 13, wherein the reflector pocket includes a gas port configured to allow a purge gas to pass through.

15. The processing chamber of claim 14, further comprising a protective region disposed between the susceptor and the heating assembly and configured to receive the purge gas from the gas port of the reflector pocket, the protective region having a height no greater than 10 mm.

16. The processing chamber of claim 9, comprising:
a plurality of warp sensors disposed on the lid and oriented toward the susceptor;
a plurality of topside thermal sensors disposed on the lid and oriented toward the susceptor; and
a plurality of backside thermal sensors disposed in the heating assembly and oriented toward the susceptor.

17. The processing chamber of claim 16, wherein the plurality of the warp sensors measure radiation at a first wavelength, the plurality of the topside thermal sensors measure radiation at a second wavelength that is shorter than the first wavelength.

18. The processing chamber of claim 9, further comprising:
a slit disposed between the upper side section and the lower side section and configured to provide an access into the processing chamber; and
a movable section disposed in front of the slit and configured to open and close the slit,
wherein the upper side section further comprises an exhaust channel and an exhaust channel liner protecting an insider surface of the exhaust channel and an exhaust outlet and an exhaust outlet liner protecting an insider surface of the exhaust outlet.

19. A method for operating a processing chamber, the method comprising:
rotating a susceptor supporting a substrate at a first rotational speed that is lower than a deposition speed;
heating the substrate to a first temperature that is lower than a deposition temperature by a heating assembly;
reducing a warpage of the substrate at the first temperature and the first rotational speed;
increasing a temperature of the substrate to the deposition temperature and a rotational speed to the deposition speed;
flowing a purge gas around a surface of a liner of the processing chamber; and
flowing a source gas into the processing chamber in a direction that is parallel with a rotational axis of the susceptor.

20. The method of claim 19 further comprising:
heating the substrate to at least 1,500° C. at a ramping up rate of no less than 10° C./second;
flowing a heat transferring fluid in the heating assembly; and
keeping a temperature of a top surface of the heating assembly to be no greater than 50° C.
